(19) United States
(12) Patent Application Publication
(10) Pub. No.: US 2011/0114159 A1
(43) Pub. Date: May 19, 2011

(54) SOLAR CELL MODULES WITH POLYMER ENCAPSULANT COMPRISING REDUCING AGENTS

(75) Inventors: Rebecca L. Smith, Vienna, WV (US); Richard Allen Hayes, Beaumont, TX (US); Katherine M. Stika, Hockessin, DE (US)

(73) Assignee: E.I. DU PONT DE NEMOURS AND COMPANY, Wilmington, DE (US)

(21) Appl. No.: 12/945,404

(22) Filed: Nov. 12, 2010

Related U.S. Application Data
(60) Provisional application No. 61/260,975, filed on Nov. 13, 2009.

(51) Int. Cl. H01L 31/048

(52) U.S. Cl. 136/251

(57) ABSTRACT

A solar cell module comprises a solar cell assembly and a polymeric encapsulant material. The polymeric encapsulant material is in contact with components of the solar cell assembly that comprise oxidizable metals, such as silver. Discoloration may result when metal cations migrate into the encapsulant material. An improved encapsulant material described herein includes one or more reducing agents to lessen or prevent this discoloration.

### CROSS-REFERENCE TO RELATED APPLICATION

This application claims priority under 35 U.S.C. §119 to U.S. Provisional Appln. No. 61/260,975, filed on Nov. 13, 2009, which is incorporated herein by reference in its entirety.

### FIELD OF THE INVENTION

The invention is directed to a solar cell module comprising a solar cell assembly and an encapsulant material. The encapsulant material comprises an improved polymer composition. In particular, the improved polymer composition is resistant to discoloration upon prolonged contact with components of the solar cell assembly that contain an elemental metal or a metal alloy.

The invention is further directed to a solar cell module comprising a solar cell assembly and an encapsulant material. The encapsulant material comprises an improved poly(vinyl butyral) composition that is resistant to discoloration in the form of yellowing upon prolonged contact with components of the solar cell assembly that comprise elemental silver and alloys of elemental silver.

### BACKGROUND OF THE INVENTION

Several patents and publications are cited in this description in order to more fully describe the state of the art to which this invention pertains. The entire disclosure of each of these patents and publications is incorporated by reference herein.

Because they provide a sustainable energy resource, the use of solar cells is rapidly expanding. Solar cells can typically be categorized into two types based on the light absorbing material used, i.e., bulk or wafer-based solar cells and thin film solar cells.

Monocrystalline silicon (c-Si), poly- or multi-crystalline silicon (poly-Si or mc-Si) and ribbon silicon are the materials used most commonly in forming the more traditional wafer-based solar cells. Solar cell modules derived from wafer-based solar cells often comprise a series of about 180 and about 240 μm thick self-supporting wafers (or cells) that are soldered together. Such a panel of solar cells, along with a layer of conductive paste and/or connecting wires deposited on its surface, may be referred to as a solar cell assembly and encapsulated by or sandwiched or laminated between polymeric encapsulants, which may be further sandwiched between two protective outer layers to form a weather resistant module. The protective outer layers may be formed of glass, metal sheets or films, or plastic sheets or films. In general, however, the outer layer that faces to the sunlight needs to be sufficiently transparent to allow photons to reach the solar cells.

The increasingly important alternative thin film solar cells are commonly formed from materials that include amorphous silicon (a-Si), microcrystalline silicon (μc-Si), cadmium telluride (CdTe), copper indium selenide (CuInSe2 or CIS), copper indium/gallium diselenide (CuInxGa(1-x)Se2 or CIGS), light absorbing dyes, and organic semiconductors. By way of example, thin film solar cells are disclosed in e.g., U.S. Pat. Nos. 5,507,881; 5,512,107; 5,948,176; 5,994,163; 6,040,521; 6,137,048; and 6,258,620 and U.S. Patent Publication Nos. 20070298590; 20070281090; 20070240759; 20070232057; 20070238285; 20070227578; 20070209699; and 20070079866. Thin film solar cells with a typical thickness of less than 2 μm are produced by depositing the semiconductor layers onto a superstrate or substrate formed of glass or a flexible film. During manufacture, it is common to include a laser scribing sequence that enables the adjacent cells to be directly interconnected in series, with no need for further solder connections between cells. As with wafer cells, the solar cell layer may further comprise electrical wirings such as cross ribbons and bus bars. Similarly, the thin film solar cells are further laminated to other encapsulant and protective layers to produce a weather resistant and environmentally robust module. Depending on the sequence in which the multi-layer deposition is carried out, the thin film solar cells may be deposited on a superstrate that ultimately serves as the incident layer in the final module, or the cells may be deposited on a substrate that ends up serving as the backing layer in the final module. Therefore, a solar cell module derived from thin film solar cells may have one of two types of construction. The first type includes, in order of position from the front light-receiving side to the back non-light-receiving side, (1) a solar cell layer comprising a superstrate and a layer of thin film solar cell(s) deposited thereon at the non-light-receiving side, (2) a (back) encapsulant layer, and (3) a backing layer. The second type may include, in order of position from the front light-receiving side to the back non-light-receiving side, (1) an incident layer, (2) a (front) encapsulant layer, (3) a solar cell layer comprising a layer of thin film solar cell(s) deposited on a substrate at the light-receiving side thereof.

The encapsulant layers used in solar cell modules are designed to encapsulate and protect the fragile solar cells. Suitable polymer materials for solar cell encapsulant layers typically possess a combination of characteristics such as high impact resistance, high penetration resistance, good ultraviolet (UV) light resistance, good long term thermal stability, adequate adhesion strength to glass and other rigid polymeric sheets, high moisture resistance, and good long term weatherability. In addition, the front encapsulant layers should be transparent enough to allow sunlight to effectively reach the solar cells to permit the solar cells to generate the highest power output possible. Thus, it is very desirable that the polymer materials utilized in the front encapsulant layers exhibit a combination of low haze and high clarity.

Within the solar cell modules, some components (such as connecting wires, conductive paste (used in wafer-based solar cell modules), conductive coatings (used in thin film solar cells) and back reflector films) may comprise an oxidizable metal or an alloy of an oxidizable metal. When in contact with an oxidizable metal component, a polymer encapsulant tends to discolor over time. Discoloration is not desirable in the photovoltaic industry, because it decreases the transmission of light, and because it may be considered aesthetically unpleasing. Accordingly, there is a need in the art to develop polymeric materials as encapsulants for solar cell modules. There is a further need to develop encapsulant materials that exhibit improved resistance to discoloration when in prolonged contact with oxidizable metal components.

### SUMMARY OF THE INVENTION

A solar cell module comprises a solar cell assembly and a polymeric encapsulant material. The polymeric encapsulant material is in contact with components of the solar cell assembly that comprise oxidizable metals, such as silver. Discoloration may result when metal cations migrate into the encapsulant material. An improved encapsulant material described herein includes one or more reducing agents to lessen or prevent this discoloration.

### DETAILED DESCRIPTION OF THE INVENTION

Unless otherwise defined, all technical and scientific terms used herein have the same meaning as commonly understood by one of ordinary skill in the art to which this invention belongs. In case of conflict, the specification, including definitions, will control.

Although methods and materials similar or equivalent to those described herein can be used in the practice or testing of the invention, suitable methods and materials are described herein.

Unless stated otherwise, all percentages, parts, ratios, etc., are by weight.

When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The term “or”, as used herein, is inclusive; that is, the phrase “A or B” means “A, B, or both A and B”. Exclusive “or” is designated herein by terms such as “either A or B” and “one of A or B”, for example.

The transitional phrase “consisting essentially of” limits the scope of a claim to the specified materials or steps and those that do not materially affect the basic and novel characteristic(s) of the claimed invention.

Where applicants have defined an invention or a portion thereof with an open-ended term such as “comprising,” it should be readily understood that unless otherwise stated the description should be interpreted to also describe such an invention using the terms “consisting essentially of” and “consisting of”.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

As used herein, the term “copolymer” refers to polymers comprising copolymerized units resulting from copolymerization of two or more comonomers. Such copolymers include dipolymers, terpolymers or higher order copolymers. In this connection, a copolymer may be described herein with reference to its constituent comonomers or to the amounts of its constituent comonomers, for example “a copolymer comprising ethylene and 18 weight % of acrylic acid”, or a similar description. Such a description may be considered informal in that it does not refer to the comonomers as copolymerized units; in that it does not include a conventional nomenclature for the copolymer, for example International Union of Pure and Applied Chemistry (IUPAC) nomenclature; in that it does not use product-by-process terminology; or for another reason. As used herein, however, a description of a copolymer with reference to its constituent comonomers or to the amounts of its constituent comonomers means that the copolymer contains copolymerized units (in the specified amounts when specified) of the specified comonomers. It follows as a corollary that a copolymer is not the product of a reaction mixture containing given comonomers in given amounts, unless expressly stated in limited circumstances to be such.

Provided herein is a polymer composition useful as an encapsulant material in solar cell modules. The polymeric encapsulant material, which comprises a polymer and a reducing agent, is resistant to discoloration over time when in at least partial contact with an oxidizable metal component within the solar cell assembly.

Suitable polymers for use in the polymeric encapsulant material include, but are not limited to, ethylene acid copolymers, ionomers of ethylene acid copolymers, poly(ethylene vinyl acetates), poly(vinyl acetals), polyurethanes, polyvinylchlorides, polyethylenes, polyolefin block copolymer elastomers, poly(α-olefin-co-α,β-ethylenically unsaturated carboxylic acid ester) copolymers, silicone elastomers, epoxy resins, polyimides, and fluoropolymer resins, and combinations of two or more of these polymers.

Preferably, the encapsulant material comprises poly(vinyl butyrals) (PVB), poly(ethylene vinyl acetates) (EVA), or ionomers of ethylene acid copolymers (neutralized ethylene methacrylic acid copolymer).

Poly(vinyl butyrals) are preferred polymers for use in the polymeric encapsulant material. Accordingly, further provided herein is a poly(vinyl butyral) (PVB) composition useful as an encapsulant in solar cell modules. The PVB encapsulant is resistant to yellowing over time when in at least partial contact with an oxidizable metal component within the solar cell assembly.

The PVB composition useful as an encapsulant material in solar cell modules comprises a PVB polymer at a level of about 85 wt %, or about 80 wt %, or about 75 to about 55 wt %, or about 65 wt %, or about 70 wt %. It further comprises one or more plasticizers at a level of about 15 wt %, or about 20 wt %, or about 25 wt % to about 45 wt %, or about 35 wt %, or about 30 wt % and one or more reducing agents at a level of at least about 0.01, 0.02, 0.05, 0.1, 0.2, 0.3, 0.4, or 0.5 wt % up to about 5.0, 4.0, 3.0, 2.0 or 1.0 wt %. Preferred ranges of the amount of reducing agent are 0.1 wt % to about 2 wt %, more preferably about 0.2 wt % to about 1 wt %, and still more preferably about 0.3 to about 0.4 wt %. The weight percentages are based on the total weight of the PVB composition. It follows as a corollary that the sum of the weight percentages of all of the components of the PVB composition is 100 wt %.

Suitable poly(vinyl butyral) polymers may be made by the condensation of a poly(vinyl alcohol) with butyraldehyde. The poly(vinyl butyral) polymers may be produced by aqueous or solvent acetalization. In a solvent process, acetalization is carried out in the presence of sufficient solvent to dissolve the poly(vinyl butyral) and produce a homogeneous solution at the end of acetalization. The poly(vinyl butyral) is separated from solution by precipitation of solid particles with water, which are then washed and dried. Solvents used are lower aliphatic alcohols such as ethanol. In an aqueous process, acetalization is carried out by adding butyraldehyde to a water solution of poly(vinyl alcohol) at a temperature of about 20° C. to about 100° C., in the presence of an acid catalyst, agitating the mixture to cause an intermediate poly(vinyl butyral) to precipitate in finely divided form and continuing the agitation while heating until the reaction mixture has proceeded to the desired end point, followed by neutralization of the catalyst, separation, stabilization and drying of the poly(vinyl butyral). For example, poly(vinyl butyral) can be produced as disclosed in U.S. Pat. No. 3,153,009 and U.S. Pat. No. 4,696,971.

Suitable PVB polymers have a weight average molecular weight of about 30,000 Da, or about 45,000 Da, or about 200,000 Da to about 600,000 Da, or about 300,000 Da, as determined by size exclusion chromatography using low angle laser light scattering. The PVB polymers may comprise about 12 wt %, or about 14 wt %, or about 15 wt %, to about 23 wt %, or about 21 wt %, or about 19.5 wt %, or about 19 wt % of hydroxyl groups calculated as polyvinyl alcohol (PVOH). The hydroxyl number can be determined according to standard methods, such as ASTM D1396-92 (1998). In addition, the PVB polymers may include up to about 10%, or up to about 3% of residual ester groups, calculated as polyvinyl ester, typically acetate groups, with the balance being butyraldehyde acetal. The PVB polymers may further comprise a minor amount of acetal groups other than butyral, for example, 2-ethyl hexanal, as disclosed in U.S. Pat. No. 5,137,954.

Any plasticizer known in the art is suitable for use in the polymer compositions described herein. See, e.g., U.S. Pat. Nos. 3,841,890; 4,144,217; 4,276,351; 4,335,036; 4,902,464; 5,013,779; and 5,886,075. Among the commonly used plasticizers are esters of a polybasic acid or a polyhydric alcohol. Specific examples of suitable plasticizers include, but are not limited to, diesters obtained from the reaction of triethylene glycol or tetraethylene glycol with aliphatic carboxylic acids having from 6 to 10 carbon atoms; diesters obtained from the reaction of sebacic acid with aliphatic alcohols having from 1 to 18 carbon atoms; oligoethylene glycol di-2-ethylhexanoate; tetraethylene glycol di-n-heptanoate; dihexyl adipate; dioctyl adipate; mixtures of heptyl and nonyl adipates; dibutyl sebacate; tributoxyethyl-phosphate; isodecylphenylphosphate; triisopropylphosphite; polymeric plasticizers, such as, the oil-modified sebacid alkyds; mixtures of phosphates and adipates; mixtures of adipates and alkyl benzyl phthalates; and combinations of two or more of the above. Preferred plasticizers for use with PVB compositions include triethylene glycol di-2-ethylhexanoate, tetraethylene glycol di-n-heptanoate, dibutyl sebacate, and combinations of two or more of these preferred plasticizers. More preferred plasticizers for PVB compositions include triethylene glycol di-2-ethylhexanoate, tetraethylene glycol di-n-heptanoate, and combinations of triethylene glycol di-2-ethylhexanoate and tetraethylene glycol di-n-heptanoate. A plasticizer of note is triethylene glycol di-2-ethylhexanoate.

The reducing agent for the polymeric encapsulant material and for the poly(vinyl butyral) composition may be selected from any material capable of reducing the oxidizable metal. Preferably, the reducing agent is selected from hydroquinones, phenidone, formic acid, citric acid, ascorbic acid, polysaccharides, primary amines, secondary amines, lithium aluminum hydride, aldehydes, formaldehyde, diboranes, dimethylaminoborane, iron metal, reducing sugars, glucose, Grignard reagents, hypophosphorous acid and derivatives thereof, hydrazine, hydroxylamines, lithium amide, lithium borohydride, calcium hydride, sodium amide, zinc metal, triethylsilane, silanehydrides, acrylamides, poly(acrylamides), poly(vinyl pyrrolidone), dimethyl formamide, polyols, glycols, glycerol, sodium dithionate, sodium sulfide, pyrocatechol and the like and combinations of two or more suitable reducing agents. More preferably, the reducing agent is selected from hydroquinones. Still more preferably, the reducing agent is hydroquinone.

Examples of suitable hydroquinones include, but are not limited to, unsubstituted or substituted aliphatic or aromatic hydroquinones. Specific examples of preferred hydroquinones include, but are not limited to, hydroquinone, 2-methylhydroquinone, 2,3-dimethylhydroquinone, 2,5-dimethylhydroquinone, 2,6-dimethylhydroquinone, 2,3,5-trimethylhydroquinone, 2,3,5,6-tetramethylhydroquinone, 2-ethylhydroquinone, 2,3-diethylhydroquinone, 2,5-diethylhydroquinone, 2,6-diethylhydroquinone, 2,3,5-triethylhydroquinone, 2,3,5,6-tetraethylhydroquinone, 2-propylhydroquinone, 2,3-dipropylhydroquinone, 2,5-dipropylhydroquinone, 2,6-dipropylhydroquinone, 2,3,5-tripropylhydroquinone, 2,3,5,6-tetrapropylhydroquinone, 2-iso-propylhydroquinone, 2,3-di-iso-propylhydroquinone, 2,5-di-iso-propylhydroquinone, 2,6-di-iso-propylhydroquinone, 2,3,5-tri-iso-propylhydroquinone, 2,3,5,6-tetra-iso-propylhydroquinone, 2-butylhydroquinone, 2,3-dibutylhydroquinone, 2,5-dibutylhydroquinone, 2,6-dibutylhydroquinone, 2,3,5-tributylhydroquinone, 2,3,5,6-tetrabutylhydroquinone, 2-tert-butylhydroquinone, 2,3-di-tert-butylhydroquinone, 2,5-di-tert-butylhydroquinone, 2,6-di-tert-butylhydroquinone, 2,3,5-tri-tert-butylhydroquinone, 2,3,5,6-tetra-tert-butylhydroquinone, 2-phenylhydroquinone, 2,3-diphenylhydroquinone, 2,5-diphenylhydroquinone, 2,6-diphenylhydroquinone, 2,3,5-triphenylhydroquinone, 2,3,5,6-tetraphenylhydroquinone, and the like and combinations of two or more suitable hydroquinones. Phenol ethers are not preferred hydroquinones.

Moreover, the reducing agents may comprise a primary or secondary amine. Examples of suitable amines include, but are not limited to, aliphatic or cycloaliphatic amines. They may be diamines, triamines, or polyamines. They may incorporate primary amine functions, secondary amine functions, or mixtures thereof. Preferably, the amine component incorporates primary amine functions. Preferably, the amine component incorporates from 2 to 100 carbon atoms. More preferably, the amine component incorporates from 2 to 50 carbon atoms. In addition, suitable primary and secondary amines are not substituted at any carbon atom that is adjacent to an amine nitrogen. Stated alternatively, the alpha carbon or carbons of suitable amines are unsubstituted.

Specific examples of preferred amines include, but are not limited to, ethylene diamine, 1,3-diaminopropane, 1,2-diaminopropane, 1,4-diaminobutane, 1,2-diamino-2-methylpropane, 1,3-diaminopentane, 1,5-diaminopentane, 2,2-dimethyl-1,3-propanediamine, 1,6-hexanediamine, 2-methyl-1,5-pentanediamine, 1,7-diaminoheptane, 1,8-diaminooctane, 1,9-diaminononane, 1,10-diaminodecane, 1,12-diaminododecane, bis(4-aminocyclohexyl)methane, diethylenetriamine, beta, beta′-diaminodiethyl ether, beta, beta′-diaminodiethyl thioether, 4,9-dioxa-1,12-dodecanediamine, 4,7,10-trioxa-1,13-tridecanediamine, N-(2-aminoethyl)-1,3-propanediamine, 3,3′ diamino-N-methyldipropylamine, 3,3′ iminobispropylamine, spermidine, bis(hexamethylene)triamine, triethylenetetramine, N,N′-bis(3-aminopropyl)ethylenediamine, N,N′-bis(2-aminoethyl)-1,3-propanediamine, N,N′-bis(3-aminopropyl)-1,3-propanediamine, spermine, tris(2-aminoethyl)amine, tetraethylenepentamine, pentaethylenehexamine, phenylene diethyl amine, 1,3-diaminomethylxylene, 4,4′ methylenebis(2-methylcyclohexylamine), 1,2-diaminocyclohexane, 1,3-diaminocyclohexane. 1,4-diaminocyclohexane, bis(1,3-aminomethyl)cyclohexane, isophorone diamine, 1,8-diamino-p-menthane, piperazine, 4,4′ trimethylenedipiperidine, and the like and mixtures thereof.

Moreover, the polymer composition may further comprise one or more unsaturated heterocylic compounds. Suitable and preferred unsaturated heterocylic compounds are described in U.S. Provisional Application Nos. 61/221,771, filed on Jun. 30, 2009, and 61/226,435, filed on Jul. 17, 2009. Briefly, however, preferred unsaturated heterocylic compounds include, without limitation, 1H-benzotriazole or non-2-H substituted benzotriazole derivatives having a formula of:

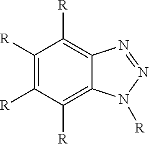

or imidazole or imidazole derivatives having a formula of:

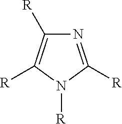

wherein R represents a hydrogen atom or a substituent; wherein, when the unsaturated heterocyclic compound comprises more than one substituent R, the substituents R are identical or different; and wherein the substituents R are selected from the group consisting of alkyl groups that are branched or unbranched, linear or cyclic; singly or multiply unsaturated hydrocarbon groups that are unbranched or branched, linear or cyclic, aromatic or non-aromatic; amino groups; hydroxyl groups; alkoxy groups; and halogen atoms; and further wherein one or more of the substituents R may optionally be substituted with one or more halogen atoms that may be the same or different or with one or more branched or unbranched alkyl groups comprising from 1 to 4 carbon atoms that may be the same or different. The heterocyclic compounds are present at a level of about 0.1 to about 2 wt %, about 0.1 to about 0.6 wt %, preferably about 0.2 to about 0.5 wt %, more preferably about 0.1 to about 0.25 wt %, based on the total weight of the polymer composition.

The polymer composition may further comprise one or more UV absorbers at a level ranging from about 0.01 wt %, or about 0.05 wt %, or about 0.08 wt % to about 1 wt %, or about 0.8 wt %, or about 0.5 wt %, based on the total weight of the polymer composition. UV absorbers are well-known in the art, and any known UV absorber may find utility within the invention. Examples of suitable UV absorbers include, but are not limited to, benzotriazole derivatives, hydroxybenzophenones, hydroxyphenyl triazines, esters of substituted and unsubstituted benzoic acids, and combinations of two or more of these suitable UV absorbers. Significantly, the benzotriazole derivatives that are useful as UV absorbers are 2-H substituted benzotriazole derivatives. Therefore, they are not included in the definitions of non-2-H substituted benzotriazole derivatives and of unsaturated heterocyclic compounds that are set forth in U.S. Provisional Application Nos. 61/221,771 and 61/226,435, cited above. Suitable commercially available UV absorbers include, but are not limited to, Tinuvin™ P, Tinuvin™ 1130, Tinuvin™ 326, Tinuvin™ 327, Tinuvin™ 328, Tinuvin™ 571, Tinuvin™ 99-DW, or Chimassob™ 81, manufactured by Ciba, Uvinul™ 3000, Uvinul™ 3008, Uvinul™ 3040, or Uvinul™ 3050, manufactured by BASF (Germany), and Cyasorb™ 5411, manufactured by Cytec Industries, Inc.

The polymer composition may further comprise one or more thermal stabilizers at a level ranging from about 0.01 wt %, or about 0.05 wt %, or about 0.08 wt % to about 1 wt %, or about 0.8 wt %, or about 0.5 wt %, based on the total weight of the polymer composition. The thermal stabilizers used here may also be referred to as phenolic antioxidants and are well known in the industry. It is noted that phenolic antioxidants may be blocked at the ortho- and para-positions to avoid hydroquinone-type activity. Examples of suitable thermal stabilizers include, but are not limited to, Irganox™ 1010, Irganox™ 1035, Irganox™ 1076, Irganox™ 1081, Irganox™ 1098, Irganox™ 1135, Irganox™ 1330, Irganox™ 1425 WL, Irganox™ 1520, Irganox™ 245, Irganox™ 3114, Irganox™ 565, Irganox™ E 201, or Irganox™ MD 1024 manufactured by Ciba, Lowinox™ 1790, Lowinox™ 22M46, Lowinox™ 44B25, Lowinox™ CA22, Lowinox™ CPL, Lowinox™ HD 98, Lowinox™ MD24, Lowinox™ TBM-6, or Lowinox™ WSP, manufactured by Chemtura (Middlebury, Conn.), Cyanox™ 1741, Cyanox™ 2246, or Cyanox™ 425, manufactured by Cytec, or combinations of two or more suitable thermal stabilizers. Thermal stabilizers of note include Lowinox™ 1790, Lowinox™ 22M46, Lowinox™ 44B25, Lowinox™ CA22, Lowinox™ CPL, Lowinox™ HD 98, Lowinox™ MD24, Lowinox™ TBM-6, or Lowinox™ WSP, or mixtures of any thereof. One preferred thermal stabilizer is octylphenol. Another preferred thermal stabilizer is butylated hydroxytoluene (BHT).

Moreover, the polymer composition may further comprise one or more hindered amines at a level of up to 1 wt %. Alternatively, the hindered amines may be present at a level ranging from about 0.08 wt %, or about 0.1 wt %, or greater than 0.1 wt %, to about 1 wt %, to about 0.8 wt %, or up to about 0.5 wt %, based on the total weight of the polymer composition. The hindered amines may be secondary or tertiary hindered amines. Examples of suitable secondary hindered amines include, but are not limited to, 2,2,6,6-tetramethyl-piperadine, 2,2,6,6-tetramethylpiper-adinol, and mixtures thereof. Examples of suitable tertiary hindered amines include, but are not limited to, N-butyl piperidine, N,N-diethyl cyclohexylamine, and combinations of two or more suitable hindered amines.

In some preferred polymer compositions, the hindered amines are hindered amine light stabilizers (HALS), which are typically secondary, tertiary, acetylated, N hydrocarbyloxy substituted, hydroxy substituted N-hydrocarbyloxy substituted, or other substituted cyclic amines which further incorporate steric hindrance, generally derived from aliphatic substitution on the carbon atoms adjacent to the amine function. As used herein, the terms “hindered amines” and “hindered amine light stabilizers” refer to compounds that are completely saturated, except for substituents that include a carbonyl group. Therefore, these terms do not refer to any of the unsaturated heterocyclic compounds described above. Hindered amine light stabilizers are also well known within the art and commercially available. For example, Tinuvin™ 111, Tinuvin™ 123, Tinuvin™ 144, Tinuvin™ 152, Tinuvin™ 292, Tinuvin™ 622, Tinuvin™ 765, Tinuvin™ 770, Tinuvin™ 783, Tinuvin™ 791, Chimassorb™ 119, Chimassorb™ 2020, or Chimassorb™ 944, manufactured by Ciba (Tarrytown, N.Y.), Cyasorb™ 3346 or Cyasorb™ 3853S manufactured by Cytec Industries, Inc. (Paterson, N.J.), or a combination of two or more suitable hindered amine light stabilizers can be used in the polymer composition.

The polymer composition may further comprise one or more chelating agents at a level ranging from about 0.01 wt %, or about 0.05 wt %, or about 0.08 wt % to about 1 wt %, or about 0.8 wt %, or about 0.5 wt %, based on the total weight of the polymer composition. Examples of suitable chelating agents include, but are not limited to, ethylenediamine tetraacetic acid (EDTA), ethylenediamine monoacetic acid, ethylene-diamine diacetic acid, ethylenediamine triacetic acid, ethylene diamine, tris(2-aminoethyl) amine, diethylenetriamine pentacetic acid, or combinations of two or more suitable chelating agents. As used herein, the term “chelating agent” does not include 2,2′-bipyridine or its derivatives.

In addition to the plasticizer and the additives listed above, the polymer composition may further comprise one or more of any other suitable additives, including, but not limited to, adhesion control additives, surface tension controlling agents, processing aids, flow enhancing additives, lubricants, pigments, dyes, flame retardants, impact modifiers, nucleating agents, anti-blocking agents such as silica, dispersants, surfactants, coupling agents, reinforcement additives, such as glass fiber, fillers and the like. These additives, suitable concentrations of the additives, and methods for incorporating them into the polymer compositions are described in the Kirk Othmer Encyclopedia of Chemical Technology, 5^{th} Edition, John Wiley & Sons (New Jersey, 2004), for example.

Further provided herein is a solar cell module that comprises a solar cell assembly, wherein the solar cell assembly comprises at least one solar cell and a metal component; the solar cell assembly is fully or partially encapsulated by a polymer encapsulant layer or layers comprising a polymer composition; and the metal component is at least partially in contact with the polymer encapsulant layer or layers.

The term “solar cell” as used herein includes any article that converts light into electrical energy. Suitable solar cells include, but are not limited to, wafer-based solar cells (e.g., c-Si or mc-Si based solar cells), thin film solar cells (e.g., a-Si, μc-Si, CdTe, or CI(G)S based solar cells), and organic solar cells. In principle, however, any type of solar cell known in the art is suitable for use in the solar cell modules described herein. The solar cells may include, but are not limited to, those described in U.S. Pat. Nos. 4,017,332; 4,179,702; 4,292,416; 6,123,824; 6,288,325; 6,613,603; and 6,784,361, U.S. Patent Publication Nos. 2006/0213548; 2008/0185033; 2008/0223436; 2008/0251120; and 2008/0271675; and PCT Patent Application Nos. WO2004/084282 and 2007/103598.

Suitable and preferred polymer compositions for use in the polymer encapsulant layer or layers are as described above with respect to the polymer compositions for polymeric encapsulant materials.

The encapsulants are preferably in the form of sheets which may have a thickness of 0.10 to about 2.4 mm (about 4 mil to about 100 mil), more preferably about 0.25 to about 1.2 mm (about 10 mil to about 50 mil). For example, when the encapsulant comprises a PVB composition, the PVB sheets preferably have a thickness of about 0.25 to about 1.2 mm (about 10 mil to about 50 mil).

The term “fully encapsulated”, as used herein, refers to a solar cell assembly that is laminated or sandwiched between two encapsulant layers comprising a polymer composition. Generally, the area of the largest surface of the solar cell assembly is smaller than that of some other components of the solar cell module, such as, for example, the substrate or superstrate, or the front or back protecting layers, or the encapsulant layer(s) before or after lamination. Therefore, in modules comprising fully encapsulated assemblies, the two polymer encapsulant layers may come in contact with each other over the edges of the solar cell assembly and form a seal around the edges of the solar cell module. When the area of the largest surface of the encapsulant layers is larger than that of the solar cell assembly, the contact between them may be established in the stacked, unlaminated solar cell module. Alternatively, when the greatest two-dimensional surface area of the encapsulant layers is smaller than that of the solar cell assembly, the contact between them may not be established until the encapsulant layers melt and flow under the heat and pressure of the solar cell module lamination process. Those of skill in the art will be able to take account of the changes necessitated in the above description by solar cell assemblies having a significant thickness.

The term “partially encapsulated”, as used herein, refers to a solar cell assembly that comprises solar cells (such as thin film solar cells) deposited on a substrate (or superstrate), has one side that is opposite from the substrate (or superstrate) laminated to an encapsulant layer comprising the polymer encapsulant composition so that the solar cell assembly is sandwiched between the substrate (or superstrate) and the polymer encapsulant layer. In modules comprising partially encapsulated assemblies, the polymer encapsulant layer may come in contact with the substrate (or superstrate) of the solar cell assembly over the edges of the solar cell module and form a seal around the edges of the solar cell assembly. Again, depending on the relative surface areas of the substrate (superstrate), the solar cell assembly and the encapsulant layer, the edge seal may form before or after the lamination process that forms the solar cell module.

The term “metal component”, as used herein, refers to a constituent part or to any sub-combination of the constituent parts of the solar cell assembly or of the solar cell module that comprises elemental metal. In particular, the terms “elemental metal”, “metallic [element]”, and “M⁰”, for example, “elemental iron”, “metallic iron” and “Fe⁰”, are synonymous and are used interchangeably herein. The elemental metal may be present in substantially neat or pure form, for example as silver is used in a reflector film. Alternatively, it may be compounded, for example with a non-metallic material such as a carrier or a filler, or it may be present in a solid solution, in an alloy, in crystalline form, as a powder or as a flake, as the continuous or dispersed phase of a dispersion, or in any other morphology. For example, the solder material used in some connecting wires is a silver and aluminum alloy containing as little as about 2 wt % of silver.

Examples of metal components in solar cell assemblies include the conductive paste, the connecting wires, the metal conductive coatings, and the metal reflector films, for example. More specifically, the conductive paste, which is typically used in wafer-based solar cells, is a conductive film deposited on the front sun-facing or back non-sun-facing side of solar cells to efficiently contact the solar cells and transport the photo-generated current. The front conductive paste, for example, may comprise elemental silver.

The term “connecting wires” as used herein also includes the solder materials used to connect the individual wires together or to anchor the wires onto the solar cells. The connecting wires, which may be included in both wafer-based solar cells and thin film solar cells, are typically soldered on the surface of the solar cells to provide electrical connections between individual solar cells and to lead the photo-generated current out of the modules. In certain embodiments, the connecting wires (including their solder material), and especially the solder material, may comprise silver or a silver alloy.

During the construction of thin film solar cells, a first conductive layer (e.g., a transparent conductive oxide (TCO) or metal coating) is first coated on the substrate before the photon absorbing materials are deposited thereon. Further, during the construction of the solar cells, a second conductive layer (e.g., a TCO or metal coating) is further deposited on the photon absorbing materials. The metal component may be one or both of these two metal conductive coatings.

Metal back reflector films are often incorporated in thin film solar cells to reflect the photons that have passed around or through the solar cells back onto the solar cells, thereby improving power generating efficiency. In certain solar cell modules, the metal back reflector film is formed by sputtering a silver layer or a silver comprising layer on the solar cells.

Moreover, the metal component may be completely or partially in contact with the encapsulant. For example, “partially in contact with” indicates that at least about 3.6×10⁻⁵% of the metal component's surface area is in contact with the encapsulant. This amount corresponds to the calculated area of scribe lines in a thin film cell, although it is also used herein to indicate a minimum surface area of contact for other metal components and in different types of solar cell modules. In contrast, the metal component is completely in contact with the encapsulant, for example in a solar cell module in which substantially 100% of the surface area of a silver reflector film is in contact with an encapsulant. When used without modification, however, as in the term “the silver component is in contact with the encapsulant,” for example, any non-zero level of contact is indicated. Stated alternatively, any non-zero percentage of the component's surface area may be in contact with the encapsulant.

The metal component comprises one or more oxidizable metals. In particular, the metals are oxidizable under the normal operating conditions of the solar cell module. Some preferred oxidizable metals are oxidizable when held under a bias of 1,000 volts for 1000 hours at 85° C. and at 85% relative humidity, in contact with the polymer encapsulant that is used in the solar cell module. More preferred oxidizable metals include bismuth, cadmium, copper, lead, silver, tin, and zinc. Silver is particularly prone to oxidation under the conditions that are found in a functioning solar cell module.

It has been found that when a prior art encapsulant material is in complete or partial contact with a metal component of a solar cell module that comprises an oxidizable metal, the prior art encapsulant tends to discolor over time. Without wishing to be bound by theory, it is believed that such discoloration results when elemental metal(M°) comprised in the metal component is oxidized, under high voltage and high moisture conditions, to form metal cations that migrate into the encapsulant. Once in the encapsulant, the metal cations are then reduced to elemental metal) (M°). The elemental metal, which may be in the form of nano-sized metal particles within the polymer matrix, is believed to cause the discoloration. By adding a reducing agent and optionally one or more of the other additives described above into the polymeric encapsulants, however, the formation of the elemental metal is lessened or prevented, and the resulting discoloration of the encapsulant is mitigated.

In a more specific example, a solar cell module comprises a solar cell assembly, wherein (A) the solar cell assembly comprises at least one solar cell and a silver component; (B) the solar cell assembly is fully or partially encapsulated by a PVB encapsulant layer or layers comprising a PVB composition as described above; and (C) the silver component is at least partially in contact with the PVB encapsulant layer or layers. When the PVB encapsulant described herein is in prolonged contact with one or more silver components, the yellowness index (YI) change of the PVB encapsulant is reduced or minimized. The YI for a PVB encapsulant can be determined in accordance with ASTM E313-05, using a 2° observer and using Illuminant C as a light source. These conditions may also be described as “2°/C”. The YI is reported in unitless numbers and must be normalized to a particular sample pathlength for direct comparison. In general, the YI of PVB encapsulants described herein remains about 60 or less, or about 55 or less, or about 50 or less, or 40 or less, or about 30 or less, or about 20 or less, for a sample having a pathlength of 1.0 cm. Also preferably, the YI of the PVB encapsulant described herein changes less than 500%, less than 350%, less than 200%, less than 100%, less than 50%, less than 25% or less than 10%, under test conditions or under solar cell module operating conditions, compared to a PVB encapsulant that does not include a reducing agent.

When the oxidizable metal is not silver, the optical effect of the metal nanoparticles may be other than yellowing. For example, the nanoparticles may cause cloudiness in the film, or they may cause discoloration to a color other than yellow. In these instances, the effect of the encapsulants described herein may be quantified by methods such as clarity measurements, electron microscopy, and optical spectroscopy. For example, for a metal whose nanoparticles cause discoloration to a color other than yellow, a method analogous to the determination of YI may be used, with the exception that a different range of visible wavelengths will be observed.

The discoloration of a polymer encapsulant in a solar cell module is difficult to measure in situ, as the discoloration of the other components in the module, such as the coatings, is difficult to deconvolute from that of the encapsulant. In order to avoid this obstacle, it is generally necessary to delaminate the module, isolating the encapsulant. Delamination is also an inconvenient procedure, however. Therefore, the discoloration of the encapsulant is generally measured using a model system. Both solid encapsulants and polymer solutions may be used as model systems for the discoloration of polymer encapsulants in solar cell modules.

For example, when a solid encapsulant is used as a model for a solar cell module having a silver component, the encapsulant is laminated to the silvered side of a silver-coated glass sheet, then held under a bias of 1,000 V for 1000 hours at 85° C. and at 85% relative humidity (RH). The solid encapsulants used as models herein have a constant plasticizer concentration, for the validity of the comparison of the encapsulants' YI. The total amount of the other additives (reducing agents, unsaturated heterocyclic compound, UV absorber, thermal stabilizer, hindered amine, chelating agent and the like) is typically about 1% or less of the amount of plasticizer in the solid encapsulants; accordingly, changes in YI due to variation in the amounts of the additives is deemed to be insignificant.

When a polymer solution is used as a model for a solar cell module having a PVB encapsulant and a silver component, a stock solution of neat PVB resin (10 g) in methanol (100 g) is combined with a stock solution of a silver salt in methanol and with stock solutions of any additives that are included in the solution model. The solution samples are incubated at 60° C. in a hot water bath for 2 to 8 hours, until the yellow color of a negative control sample becomes apparent to the naked eye. The samples are transferred to cuvettes having a pathlength of 1.0 cm, and their spectra are obtained according to the standard method. The concentrations of the PVB and of the silver (calculated as silver ions) in the solution samples are held constant, again for validity of comparison of the solutions' YI.

In one preferred solar cell module, the solar cells are wafer-based solar cells, and the metal component may be a conductive paste or one or more connecting wires. The metal component is in contact with the encapsulant and the encapsulant comprises a polymer composition. Further, the solar cell assembly, which comprises the wafer-based solar cells and the silver component, and which is encapsulated by the polymer encapsulant, may be further sandwiched between two protective outer layers which are also referred to as the front and back sheets.

The protective outer layers of the solar cell modules may be formed of any suitable sheets or films. Suitable sheets include glass sheets, metal sheets such as aluminum, steel, galvanized steel, ceramic plates, or plastic sheets, such as polycarbonates, acrylics, polyacrylates, cyclic polyolefins (e.g., ethylene norbornene polymers), polystyrenes (preferably polystyrenes prepared in the presence of metallocene catalysts), polyamides, polyesters, fluoropolymers, or combinations of two or more thereof.

Suitable films include metal films, such as aluminum foil, or polymeric films, such as those comprising polyesters (e.g., poly(ethylene terephthalate) and poly(ethylene naphthalate)), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), nylons, poly(urethanes), acrylics, cellulose acetates (e.g., cellulose acetate, cellulose triacetates, etc.), cellophane, silicones, poly(vinyl chlorides) (e.g., poly(vinylidene chloride)), fluoropolymers (e.g., polyvinyl fluoride, polyvinylidene fluoride, polytetrafluoroethylene, ethylene-tetrafluoroethylene copolymers, etc.), or combinations of two or more thereof. The polymeric film may be non-oriented, or uniaxially oriented, or biaxially oriented. Some specific examples of suitable polymeric films include, but are not limited to, polyester films (e.g., poly(ethylene terephthalate) films), fluoropolymer films (e.g., Tedlar®, Tefzel®, and Teflon® films available from E. I. du Pont de Nemours and Company (DuPont), Wilmington, Del.). Further, the films may be in the form of a multi-layer film, such as a fluoropolymer/polyester/fluoropolymer multilayer film (e.g., Tedlar®/PET/Tedlar® or TPT laminate film available from Isovolta AG., Austria or Madico, Woburn, Mass.).

In another preferred solar cell module, the solar cells are thin film solar cells, and the metal component may be selected from connecting wires, conductive coatings, or back reflector films, or a combination of two or more thereof. In one particular thin film solar cell, the metal component is a conductive coating. The metal component may also be a back reflector film. Similarly to the above described wafer-based solar cell modules, the thin film solar cell assembly is fully or partially encapsulated by the encapsulant, and the metal component is in contact with the encapsulant. Again, the fully or partially encapsulated thin film solar cell assembly may be further sandwiched between two additional protective outer layers, such as a front or back sheet. Alternatively, the thin film solar cell assembly may be partially encapsulated by the encapsulant, e.g., having its side that is opposite from the substrate (or superstrate) laminated to the encapsulant, which is further laminated to a protective outer layer. More preferably, the thin film solar cell assembly comprises a silver comprising reflector film, which is in contact with the PVB encapsulant.

In another preferred thin film solar cell module, the light absorbing materials are deposited on a substrate in layers. The substrate may be made of glass, or any suitable metal, or polymeric sheets or films as described above for the protective outer layers. The thin film solar cells may be single-junction or multi-junction (including tandem junction) thin film solar cells. As the spectrum of solar energy provides photons of varying energies, multi-junction solar cells were developed so that the sunlight may pass serially through several solar cell layers. Each separate layer is tailored for efficient conversion to electrical energy of photons of a specific energy range. The multi-junction solar cells are usually constructed with layers of different energy gaps with a higher energy gap layer adjacent to the surface through which the light enters the module. Consistently, the lower energy gap layers are positioned further towards the middle of the module.

Any suitable process may be used in preparing the solar cell modules described herein. In particular, any suitable lamination process known in the art (such as an autoclave or a non-autoclave process) may be used to prepare the solar cell modules. For example, in a typical lamination process, the solar cells are first stacked between the encapsulants (e.g., in the form of PVB sheets), and this stack is further stacked between two protective films or sheets. The entire assembly is then subjected to the lamination process. Further, in the preparation of thin film solar cell modules, the solar cells, which are deposited over a substrate, are first stacked over the encapsulant (e.g., in the form of a PVB sheet) and than a protective film or sheet, before being subjected to the lamination process.

In an example of a suitable process, the assembly is placed into a bag capable of sustaining a vacuum (“a vacuum bag”), the air is drawn out of the bag by a vacuum line or other means, the bag is sealed while the vacuum is maintained (e.g., at least about 27-28 in Hg (689-711 mm Hg)), and the sealed bag is placed in an autoclave at a pressure of about 150 to about 250 psi (about 11.3 to about 18.8 bar), a temperature of about 130° C. to about 180° C., or about 120° C. to about 160° C., or about 135° C. to about 160° C., or about 145° C. to about 155° C., for about 10 to about 50 min, or about 20 to about 45 min, or about 20 to about 40 min, or about 25 to about 35 min. A vacuum ring may be substituted for the vacuum bag. One type of suitable vacuum bag is disclosed within U.S. Pat. No. 3,311,517. Following the heat and pressure cycle, the air in the autoclave is cooled without adding additional gas to maintain pressure in the autoclave. After about 20 min of cooling, the excess air pressure is vented and the laminates are removed from the autoclave.

Alternatively, the pre-lamination assembly may be heated in an oven at about 80° C. to about 120° C., or about 90° C. to about 100° C., for about 20 to about 40 min, and thereafter, the heated assembly is passed through a set of nip rolls so that the air in the void spaces between the individual layers may be squeezed out, and the edge of the assembly sealed. The assembly at this stage is referred to as a pre-press.

The pre-press may then be placed in an air autoclave where the temperature is raised to about 120° C. to about 160° C., or about 135° C. to about 160° C., at a pressure of about 100 to about 300 psi (about 6.9 to about 20.7 bar), or preferably about 200 psi (13.8 bar). These conditions are maintained for about 15 to about 60 min, or about 20 to about 50 min, and after which, the air is cooled while no more air is added to the autoclave. After about 20 to about 40 min of cooling, the excess air pressure is vented and the laminated products are removed from the autoclave.

The solar cell modules may also be produced through non-autoclave processes. Suitable non-autoclave processes are described, e.g., in U.S. Pat. Nos. 3,234,062; 3,852,136; 4,341,576; 4,385,951; 4,398,979; 5,536,347; 5,853,516; 6,342,116; and 5,415,909, U.S. Patent Publication No. 20040182493, European Patent No. EP1235683 B1, and PCT Patent Publication Nos. WO9101880 and WO03057478. Generally, the non-autoclave processes include heating the pre-lamination assembly and the application of vacuum, pressure or both. For example, the assembly may be successively passed through heating ovens and nip rolls.

These examples of lamination processes are not intended to be limiting. Any lamination process that is operative may be used.

Further provided herein are: a solar cell array comprising two or more of the solar cell modules described above; a process for converting light energy to electricity, said process comprising the step of exposing a solar cell assembly or a solar cell module to electromagnetic radiation; and a process for converting solar energy to electricity, said process comprising the step of exposing a solar cell assembly or a solar cell module to solar radiation.

The Examples below are provided to describe the invention in further detail. These Examples, which set forth a preferred mode presently contemplated for carrying out the invention, are intended to illustrate and not to limit the invention.

### EXAMPLES

### Control Example CE1

A commercially available Butacite® PVB sheet from DuPont, which comprises 72.97 wt % of poly(vinyl butyral), 26.7 wt % of triethyleneglycol di-2-ethyl-hexanoate, 0.1 wt % of Tinuvin™ P Benzotriazole UV Absorber (Ciba), 0.003 wt % of Tinuvin™ 123 hindered amine light stabilizer (HALS) (Ciba), and 0.22 wt % octylphenol, based on the total weight of the PVB composition, was laminated to a silver coated glass sheet at the silver coated side. After 1000 hours of conditioning at 85% relative humidity (RH), 85° C. and under a bias of 1000 V, the PVB sheet changed color from near water white to dark brown.

### Control Examples CE2 and CE3 and Example E1

Solutions of dried neat PVB resin (6.9×10⁻⁵ mol), silver nitrate (1.2×10⁻⁵ mol), and additive(s) were prepared by mixing a solution of silver nitrate and additives in methanol with a solution of PVB flake in methanol. The PVB resin had a residual OH level of 18.8 wt %, as determined by ASTM E222-00 (2005)e1 (Standard Test Methods for Hydroxyl Groups Using Acetic Anhydride Acetylation, Test B, Reflux Method), and a molecular weight of greater than 125,000 Da, as determined by size exclusion chromatography. Two control solutions (CE2 and CE3), one of PVB in methanol without additives and one of PVB and silver nitrate in methanol without additives, were also prepared.

The solutions were heated at 60° C. for two to eight hours. Their color change was monitored by measurement with a HunterLab Ultrascan Colorimeter (Hunter Labs, Reston, Va.). Yellowness index (YI) was calculated by ASTM E313-05, using a 2° observer and Illuminant C (2°/C), and normalized to a 1.0 cm pathlength. As a result of the addition of silver nitrate to the PVB/methanol solution, the yellowness index (YI) was changed from 6 (in Control Example CE2) to 290.1 (in Control Example CE3).

In Example E1, hydroquinone (0.4 wt % based on PVB resin) is added to the solution of Control Example CE3. The solution is heated at 60° C. for two to eight hours. The color change is monitored and the YI is calculated as described above for Control Examples CE2 and CE3. The YI of Example E1 is reduced compared to the PVB/silver nitrate/methanol control solution, Control Example CE3. Addition of one or more optional unsaturated heterocycles, UV absorbers, or hindered amines to the solution of E1 provides a further reduction of YI.

### Control Example CE4 and Example E2

In Example E2, 72.56 wt % of the dried neat PVB resin used in Example E1 is blended with a solution of 0.4 wt % hydroquinone, 0.12 wt % Tinuvin™ P, and 0.22 wt % octylphenol in 26.7 wt % triethylene glycol di-2-ethylhexanoate. This blend is fed into a single screw extruder and melted at a temperature of 200° C., nominally. The resulting melt is pressed into a 30 mil thick sheet, and the sheet is laminated between a first float glass sheet and a second float glass sheet. The second float glass sheet has a silver coating (200 nm thick) on the side that is laminated in contact with the PVB sheet. The laminate of Control Example CE4 has the same structure, except that the PVB sheet comprises 72.96 wt % PVB resin, 26.7 wt % triethylene glycol di-2-ethylhexanoate, 0.12 wt % Tinuvin™ P, and 0.22 wt % octylphenol.

The laminates of Control Example CE4 and Example E2 are placed into a chamber held at 85° C. and 85% relative humidity (RH) for 1000 hours and subjected to a bias of 1000 V. After this exposure, the PVB sheet in the laminate of Control Example CE4 is more discolored than the PVB sheet in the laminate of Example E2.

While certain of the preferred embodiments of the present invention have been described and specifically exemplified above, it is not intended that the invention be limited to such embodiments. Various modifications may be made without departing from the scope and spirit of the present invention, as set forth in the following claims.

What is claimed is:

1. A solar cell module comprising a solar cell assembly comprising one or more solar cells and a polymer encapsulant; wherein the solar cell assembly further comprises one or more metal components; wherein the metal component comprises an oxidizable metal; wherein the metal component is at least partially in contact with the polymer encapsulant; and wherein the polymer encapsulant comprises a reducing agent.

2. The solar cell module of claim 1, wherein the oxidizable metal is oxidizable under the operating conditions of the solar cell module.

3. The solar cell module of claim 1, wherein the oxidizable metal is oxidizable when held under a bias of 1,000 volts for 1000 hours at 85° C. and at 85% relative humidity, in contact with the polymer encapsulant.

4. The solar cell module of claim 1, wherein the polymer encapsulant comprises one or more polymers selected from the group consisting of ethylene acid copolymers, ionomers of ethylene acid copolymers, poly(ethylene vinyl acetates), poly(vinyl acetals), polyurethanes, polyvinylchlorides, polyethylenes, polyolefin block copolymer elastomers, poly(α-olefin-co-α,β-ethylenically unsaturated carboxylic acid ester) copolymers, silicone elastomers, epoxy resins, polyimides, and fluoropolymer resins.

5. The solar cell module of claim 1, wherein the polymer encapsulant comprises at least about 0.01 wt % up to about 5.0 wt % of one or more reducing agents.

6. The solar cell module of claim 1, wherein the reducing agent comprises one or more materials selected from the group consisting of hydroquinones, phenidone, formic acid, citric acid, ascorbic acid, polysaccharides, primary amines, secondary amines, lithium aluminum hydride, aldehydes, formaldehyde, diboranes, dimethylaminoborane, iron metal, reducing sugars, glucose, Grignard reagents, hypophosphorous acid and derivatives thereof, hydrazine, hydroxylamines, lithium amide, lithium borohydride, calcium hydride, sodium amide, zinc metal, triethylsilane, silanehydrides, acrylamides, poly(acrylamides), poly(vinyl pyrrolidone), dimethyl formamide, polyols, glycols, glycerol, sodium dithionate, sodium sulfide, and pyrocatechol.

7. The solar cell module of claim 1, wherein the reducing agent(s) are selected from the group consisting of hydroquinones, phenidone, formic acid, citric acid, ascorbic acid, polysaccharides, primary amines, and secondary amines.

8. The solar cell module of claim 1, wherein the polymer encapsulant further comprises 0.01 to 0.25 wt % of one or more adjuvants selected from the group consisting of unsaturated heterocyclic compounds, UV absorbers, thermal stabilizers, hindered amine light stabilizers, and chelating agents.

9. The solar cell module of claim 1, wherein the metal component is selected from the group consisting of conductive pastes, connecting wires, conductive coatings, and reflector films.

10. The solar cell module of claim 1, wherein the oxidizable metal is selected from the group consisting of bismuth, cadmium, copper, lead, silver, tin, and zinc.

11. The solar cell module of claim 1, wherein the oxidizable metal consists essentially of silver.

12. The solar cell module of claim 11, wherein the metal component comprises at least about 2 wt % of elemental silver.

13. The solar cell module of claim 11, wherein the metal component comprises a silver alloy, and wherein the alloy comprises at least about 2 wt % of elemental silver.

14. The solar cell module of claim 11, wherein the metal component is a reflector film comprising a silver alloy.

15. The solar cell module of claim 1, wherein the solar cells comprise wafer-based solar cells selected from the group consisting of monocrystalline silicon (c-Si) and multi-crystalline silicon (mc-Si) based solar cells; or wherein the solar cells comprise thin film solar cells that comprise one or more materials selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductors.

16. The solar cell module of claim 15, wherein the metal component is a reflector film and wherein the oxidizable metal is silver.

17. Use of the solar cell module of claim 1 to convert solar energy to electricity.

18. A solar cell module comprising a solar cell assembly comprising one or more solar cells and a poly(vinyl butyral) encapsulant, wherein (i) the solar cell assembly further comprises a silver component, (ii) the silver component comprises elemental silver; (iii) the silver component is in contact with the poly(vinyl butyral) encapsulant; (iv) the poly(vinyl butyral) encapsulant comprises a poly(vinyl butyral) polymer, about 15 to about 45 wt % of plasticizer, and about 0.3 to about 2 wt % of one or more reducing agents selected from the group consisting of hydroquinone, phenidone, formic acid, citric acid, ascorbic acid, polysaccharides, primary amines, and secondary amines; wherein the weight percentages are based on the total weight of the poly(vinyl butyral) encapsulant.

19. The solar cell module of claim 18, wherein the reducing agent comprises hydroquinone.

20. The solar cell module of claim 18, wherein the poly(vinyl butyral) encapsulant further comprises one or more adjuvants selected from the group consisting of about 0.1 to about 2 wt % of one or more unsaturated heterocyclic compounds; about 0.01 to about 1 wt % of one or more UV absorbers; about 0.01 to about 1 wt % of one or more thermal stabilizers; about 0.01 to about 1 wt % of one or more hindered amines; and about 0.01 to about 1 wt % of one or more chelating agents, based on the total weight of the poly(vinyl butyral) encapsulant.

21. The solar cell module of claim 20, wherein the unsaturated heterocyclic compound(s) are selected from the group consisting of 1H-benzotriazole, non-2H-substituted benzotriazoles, imidazole and imidazole derivatives; wherein the UV absorber(s) are selected from the group consisting of 2-H substituted benzotriazole derivatives; wherein the thermal stabilizer(s) are selected from the group consisting of octylphenol, butylated hydroxytoluene (BHT); wherein the hindered amine(s) are hindered amine light stabilizers; and wherein the one or more chelating agent(s) are selected from the group consisting of ethylenediamine-tetraacetic acid (EDTA), ethylenediamine monoacetic acid, ethylenediamine diacetic acid, ethylenediamine triacetic acid, ethylene diamine, tris(2-aminoethyl) amine, and diethylenetriaminepentacetic acid.

22. The solar cell module of claim 18, wherein the silver component consists of substantially pure silver metal.

23. The solar cell module of claim 18, wherein the silver component comprises at least about 2 wt % of elemental silver.

24. The solar cell module of claim 18, wherein the silver component comprises a silver alloy, and wherein the alloy comprises at least about 2 wt % of elemental silver.

25. The solar cell module of claim 18, wherein the silver component is selected from the group consisting of conductive pastes, connecting wires, conductive coatings, and reflector films.

26. The solar cell module of claim 18, wherein the solar cells comprise wafer-based solar cells selected from the group consisting of monocrystalline silicon (c-Si) and multi-crystalline silicon (mc-Si) based solar cells; or wherein the solar cells comprise thin film solar cells that comprise one or more materials selected from the group consisting of amorphous silicon (a-Si), microcrystalline silicon (μc-Si), cadmium telluride (CdTe), copper indium selenide (CIS), copper indium/gallium diselenide (CIGS), light absorbing dyes, and organic semiconductors.

27. The solar cell module of claim 26, wherein the silver component is a reflector film.

28. A process for preventing discoloration of poly(vinyl butyral) encapsulant in a solar cell module comprising a solar cell assembly that comprises a silver component in complete or partial contact with the poly(vinyl butyral) encapsulant, said process comprising the steps of
providing a poly(vinyl butyral) encapsulant comprising a poly(vinyl butyral) polymer, about 15 to about 45 wt % of one or more plasticizers, and about 0.3 to about 2 wt % of one or more reducing agents selected from the group consisting of hydroquinone, phenidone, formic acid, citric acid, ascorbic acid, polysaccharides, primary amines, and secondary amines, wherein the weight percentages are based on the total weight of the poly(vinyl butyral) encapsulant; and
encapsulating the solar cell assembly with the poly(vinyl butyral).

29. Use of the solar cell module of claim 18 to convert solar energy to electricity.
